(19) United States
(12) Patent Application Publication
(10) Pub. No.: US 2025/0157892 A1
(43) Pub. Date: May 15, 2025

(54) SEMICONDUCTOR DEVICE

(71) Applicant: FUJI ELECTRIC CO., LTD., Kawasaki-shi (JP)

(72) Inventors: Takahiro KOYAMA, Matsumoto-city (JP); Kensuke MATSUZAWA, Matsumoto-city (JP); Taisuke FUKUDA, Matsumoto-city (JP); Daisuke INOUE, Matsumoto-city (JP)

(73) Assignee: FUJI ELECTRIC CO., LTD., Kawasaki-shi (JP)

(21) Appl. No.: 18/899,366

(22) Filed: Sep. 27, 2024

(30) Foreign Application Priority Data
Nov. 14, 2023 (JP) 2023-193656

(51) Int. Cl. H01L 23/49; H01L 23/00; H01L 23/31; H01L 23/367; H01L 23/492; H01L 25/07

(52) U.S. Cl. CPC H01L 23/49; H01L 23/3107; H01L 23/367; H01L 23/492; H01L 24/32; H01L 24/35; H01L 24/40; H01L 24/48; H01L 24/73; H01L 25/072; H01L 2224/32245; H01L 2224/352; H01L 2224/40139; H01L 2224/40155; H01L 2224/73221; H01L 2224/73263; H01L 2224/73265; H01L 2924/10272; H01L 2924/13091

(57) ABSTRACT

A semiconductor device includes: a conductive substrate; a plurality of semiconductor chips provided on the conductive substrate; a printed wiring board including a first conductive layer provided on the conductive substrate, an insulating layer provided on the first conductive layer, and a second conductive layer provided on the insulating layer and electrically connected to respective first electrodes of the semiconductor chips; and a first external terminal provided on the second conductive layer to extend upward from the second conductive layer.

### CROSS-REFERENCE TO RELATED APPLICATION

This application claims benefit of priority under 35 USC 119 based on Japanese Patent Application No. 2023-193656 filed on Nov. 14, 2023, the entire contents of which are incorporated by reference herein.

### BACKGROUND OF THE INVENTION

### 1. Field of the Invention

The present disclosure relates to semiconductor devices (power semiconductor modules) equipped with power semiconductor elements.

### 2. Description of the Related Art

WO2021/079913A1 and JP2021-190505A each disclose a semiconductor device in which a gate layer is provided on a main surface metal layer with an insulating layer interposed, and a gate terminal is connected to the gate layer via a bonding wire. JP2019-149460A discloses that an insulated circuit substrate includes a ceramic substrate, and a circuit layer provided on one of the surfaces of the ceramic substrate, in which the circuit layer has a stacked structure including a first circuit layer bonded to one of the surfaces of the ceramic substrate, and a second circuit layer further bonded to the surface of the first circuit layer.

JP2018-137396A discloses a method of manufacturing a substrate including a ceramic base body and plural metal plates made from common material and having a common shape and thickness provided on both surfaces of the ceramic base body with bonding material interposed, the method applying pressure and heat to the obtained stacked body in the stacked direction to be bonded together, and then cooling the stacked body, so as to provide a circuit layer and a metal layer having a symmetric shape with the ceramic base body interposed. WO2019/167931A1 discloses an insulated circuit substrate including a ceramic substrate, a circuit layer that is bonded to one surface of the ceramic substrate and provided with a circuit pattern, and a metal layer bonded to the other surface of the ceramic substrate, wherein the circuit layer includes a first circuit layer that is bonded to the ceramic substrate and a second circuit layer that is bonded to a top surface of the first circuit layer, and the metal layer includes a first metal layer that is bonded to the ceramic substrate and a second metal layer that is bonded to a top surface of the first metal layer.

JP2016-092283A discloses a circuit substrate including a first conductive layer, a first insulating substrate, a second conductive layer, and a second insulating substrate stacked in this order, and further including a third conductive layer and a fourth conductive layer stacked on the second insulating substrate. JP2006-269966A discloses a wired substrate including a heat-releasing plate, an insulating layer fixed to the heat-releasing plate, and a conductive wired circuit portion fixed to a surface of the insulating layer opposite to the heat-releasing plate, wherein the insulating layer includes at least one resin layer, and the heat-releasing plate and the wired circuit portion have substantially the same coefficient of thermal expansion and thickness.

JP2020-021886A discloses a module including an insulating substrate, a first heat-conducting body and a second heat-conducting body arranged on the insulating substrate, a first substrate and a second substrate provided on the first heat-conducting body and the second heat-conducting body, and a first signal terminal and a second signal terminal provided on the first substrate and the second substrate. WO2019/098368A1 discloses a semiconductor device including a gate layer provided on a conductive plate with a substrate interposed, and a gate terminal connected to the gate layer via a bonding wire.

JP2020-077762A discloses a semiconductor device including wiring layers and gate wiring layers provided on the wiring layers with insulating plates interposed, and gate terminals connected to the gate wiring layers via wires. WO2019/235146A1 discloses a semiconductor module including a gate layer on a conductive member with an insulating substrate interposed, and a gate terminal connected to the gate layer via a wire.

WO2017/163612A1 discloses a semiconductor module provided with a pattern for signal control on a conductive plate with an insulating plate interposed, the module including a control signal terminal connected to the pattern for signal control via a bonding wire. JP2007-281443A discloses a semiconductor device including a gate electrode terminal extending under a plurality of chips.

JP2021-141219A discloses a semiconductor module having a structure in which an end of a gate terminal and a gate relay layer are connected to each other via a gate wire. JP2021-141220A discloses a semiconductor module including a control wired substrate provided between semiconductor chips and including a gate wiring layer and a source wiring layer, in which a gate terminal and the gate wiring layer are connected to each other via a gate wire.

JP2014-192976A discloses a semiconductor device including a substrate, a first switching element and a second switching element provided on the substrate, and a conductive wire provided in the substrate and connected to a signal terminal of the first switching element. WO2016/125635A1 discloses a silicon nitride circuit board including metal plates attached to both front and rear surfaces of a silicon nitride substrate provided with a warp.

U.S. Pat. No. 8,981,545B2 and U.S. Pat. No. 9,659,912B2 each discloses a configuration in which semiconductor chips are arranged on both sides of a printed wiring board.

JP2018-073923A discloses a semiconductor device including an aluminum plate and a lead pattern provided on the aluminum plate via bonding resin, wherein insertion terminals having press-fit parts are inserted into insertion holes of the lead pattern.

Such a conventional power semiconductor module as described above, when having a configuration in which semiconductor chips are provided on a conductive substrate so that the semiconductor chips are electrically connected to a printed wiring board provided on the conductive substrate via lead frames or bonding wires, inevitably leads to an increase in size if the printed wiring board is connected to external terminals by wire bonding or via lead frames.

### SUMMARY OF THE INVENTION

In view of the foregoing problems, the present disclosure provides a semiconductor device including semiconductor chips provided on a conductive substrate and a printed wiring board electrically connected to each other with a configuration contributing to a reduction in size.

An aspect of the present disclosure inheres in a semiconductor device including: a conductive substrate; a plurality of semiconductor chips each having a first electrode and provided on the conductive substrate; a printed wiring board including a first conductive layer provided on the conductive substrate, an insulating layer provided on the first conductive layer, and a second conductive layer provided on the insulating layer and electrically connected to the respective first electrodes of the semiconductor chips; and a first external terminal provided on the second conductive layer to extend upward from the second conductive layer.

In the semiconductor device the first external terminal may include: a support part provided on the second conductive layer; and an extending part supported by the support part to extend upward over the second conductive layer.

In the semiconductor device, the support part may have an opening, and an end of the extending part may be press-fitted to the opening.

In the semiconductor device, the insulating layer has a planar pattern including: a first region extending in one direction between the plural semiconductor chips; and a second region extending in a direction perpendicular to the first region.

In the semiconductor device, the second conductive layer may be arranged across the first region and the second region.

In the semiconductor device, the semiconductor device may further include a plurality of the first external terminals, the printed wiring board may further include a plurality of the second conductive layers aligned on the second region, and the first external terminals may be provided on the respective second conductive layers to so as be arranged in line.

In the semiconductor device, the plural semiconductor chips each may further have a second electrode, the semiconductor device may further includes: a sealing resin provided to seal the respective semiconductor chips; and a second external terminal electrically connected to the respective second electrodes of the semiconductor chips, a part of the first external terminal may project from a top surface of the sealing resin, and a part of the second external terminal may project from a side surface of the sealing resin.

It should be noted that the above summary of the invention does not list all the necessary features of the present disclosure. Subcombinations of these feature groups can also be inventions.

### BRIEF DESCRIPTION OF THE DRAWINGS

FIG. 1 is a perspective view illustrating a semiconductor device according to a first embodiment;

FIG. 2 is a plan view corresponding to FIG. 1;

FIG. 3 is a partly-omitted perspective view illustrating the semiconductor device according to the first embodiment;

FIG. 4 is a plan view corresponding to FIG. 3;

FIG. 5 is a side view corresponding to FIG. 3 and FIG. 4;

FIG. 6 is an enlarged side view of region A illustrated in FIG. 5;

FIG. 7 is a partly-omitted perspective view illustrating the semiconductor device according to the first embodiment;

FIG. 8 is a plan view corresponding to FIG. 7;

FIG. 9 is a cross-sectional view illustrating a part of a packaged structure of the semiconductor device according to the first embodiment;

FIG. 10 is a cross-sectional view illustrating a control terminal of the semiconductor device according to the first embodiment;

FIG. 11 is a perspective view illustrating a conductive member of the semiconductor device according to the first embodiment;

FIG. 12 is a perspective view illustrating a negative electrode terminal of the semiconductor device according to the first embodiment;

FIG. 13 is a perspective view illustrating a resin member of the semiconductor device according to the first embodiment;

FIG. 14 is side view illustrating a packaged structure of the semiconductor device according to the first embodiment;

FIG. 15 is an equivalent circuit diagram of the semiconductor device according to the first embodiment;

FIG. 16 is a partly-omitted perspective view illustrating a semiconductor device according to a second embodiment;

FIG. 17 is a plan view corresponding to FIG. 16;

FIG. 18 is a perspective view illustrating a resin member of the semiconductor device according to the second embodiment;

FIG. 19 is a side view illustrating a laminated structure body of the semiconductor device according to the second embodiment;

FIG. 20 is an enlarged side view of region A illustrated in FIG. 19;

FIG. 21 is a side view for explaining a method of assembling the laminated structure body illustrated in FIG. 19;

FIG. 22 is a perspective view illustrating a conductive member of a semiconductor device according to a modified example of the second embodiment; and

FIG. 23 is a perspective view illustrating a resin member of the semiconductor device according to the modified example of the second embodiment.

### DETAILED DESCRIPTION

With reference to the drawings, first and second embodiments of the present disclosure will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

Additionally, definitions of directions such as “upper”, “lower”, “upper and lower”, “left”, “right”, and “left and right” in the following description are simply definitions for convenience of description, and do not limit the technological concept of the present disclosure. For example, when observing an object rotated by 90°, the “upper and lower” are converted to “left and right” to be read, and when observing an object rotated by 180°, the “upper and lower” are read reversed, which should go without saying. In addition, a “top surface” and a “bottom surface”, respectively, may be read as “front surface” and “back surface”. In addition, the “first main surface” and the “second main surface” of each member are main surfaces facing each other. For example, if the “first main surface” is the top surface, the “second main surface” is the bottom surface.

### First Embodiment

### <Structure of Semiconductor Device>

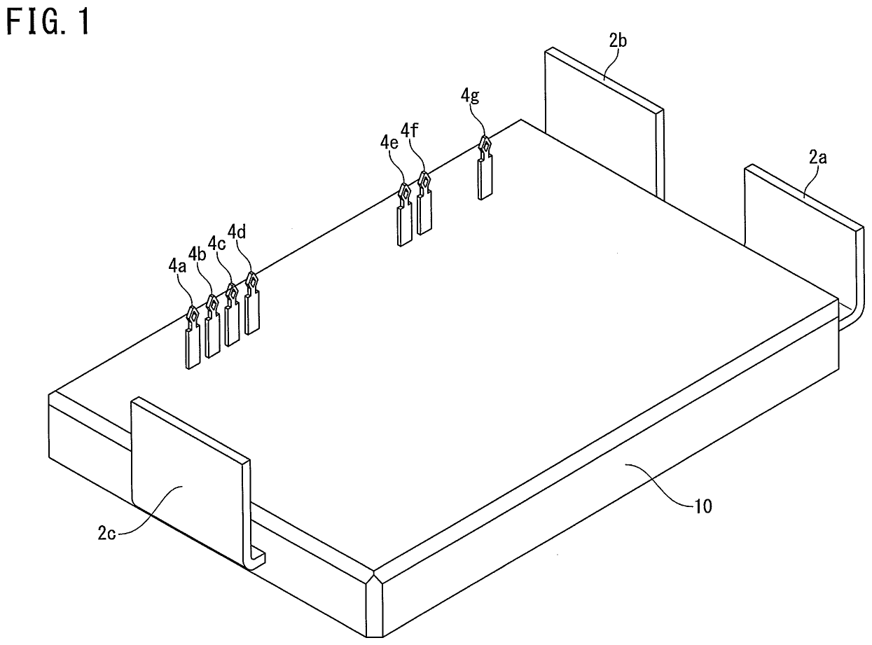

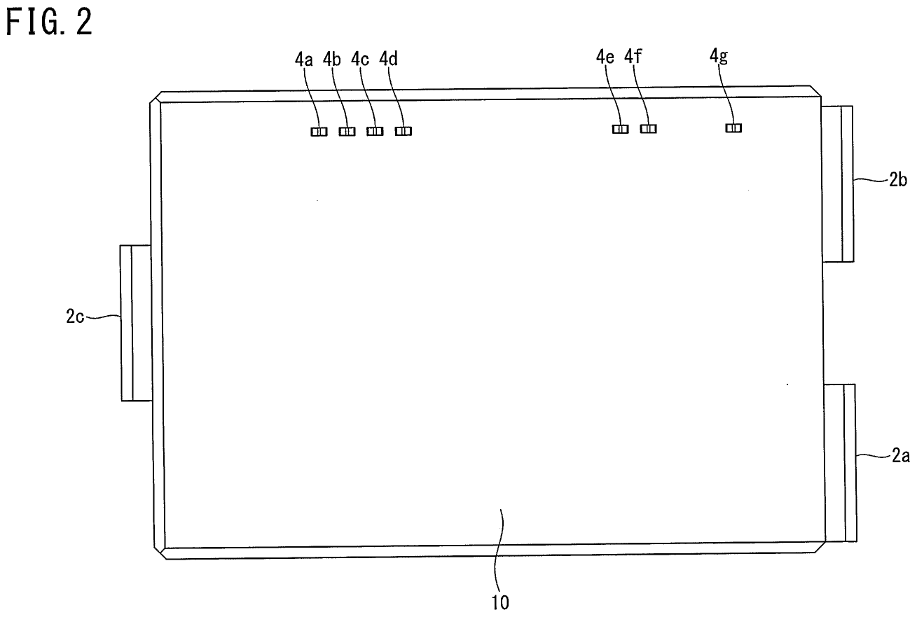

FIG. 1 is a perspective view illustrating a semiconductor device (a power semiconductor module) according to a first embodiment, and FIG. 2 is a plan view illustrating the semiconductor device according to the first embodiment. As illustrated in FIG. 1 and FIG. 2, the semiconductor device according to the first embodiment includes a sealing resin 10 for sealing power semiconductor elements (semiconductor chips), a second external terminal (a negative electrode terminal) 2a, a second external terminal (a positive electrode terminal) 2b, a second external terminal (an output terminal) 2c, and first external terminals (control terminals) 4a to 4g, the respective terminals projecting from the sealing resin 10.

The sealing resin 10 has a substantially cuboidal shape. The negative electrode terminal 2a and the positive electrode terminal 2b each project from the common side surface of the sealing resin 10 having the substantially cuboidal shape. The output terminal 2c projects from the side surface of the substantially cuboidal shape of the sealing resin 10 on the side opposite to the negative electrode terminal 2a and the positive electrode terminal 2b. The respective control terminals 4a to 4g project from the top surface of the substantially cuboidal shape of the sealing resin 10 located between the surface from which the negative electrode terminal 2a and the positive electrode terminal 2a project and the surface from which the output terminal 2c projects.

The sealing resin 10 includes material having insulating properties such as epoxy resin. The output terminal 2c, the positive electrode terminal 2b, the negative electrode terminal 2a, and the control terminals 4a to 4g each include conductive material such as copper (Cu), a Cu alloy, aluminum (Al), and an Al alloy.

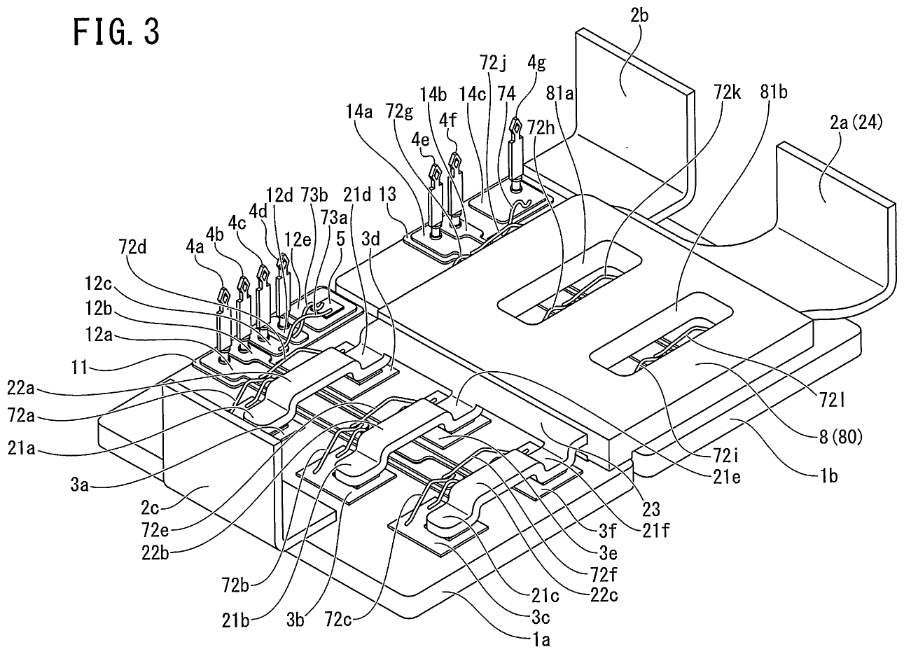

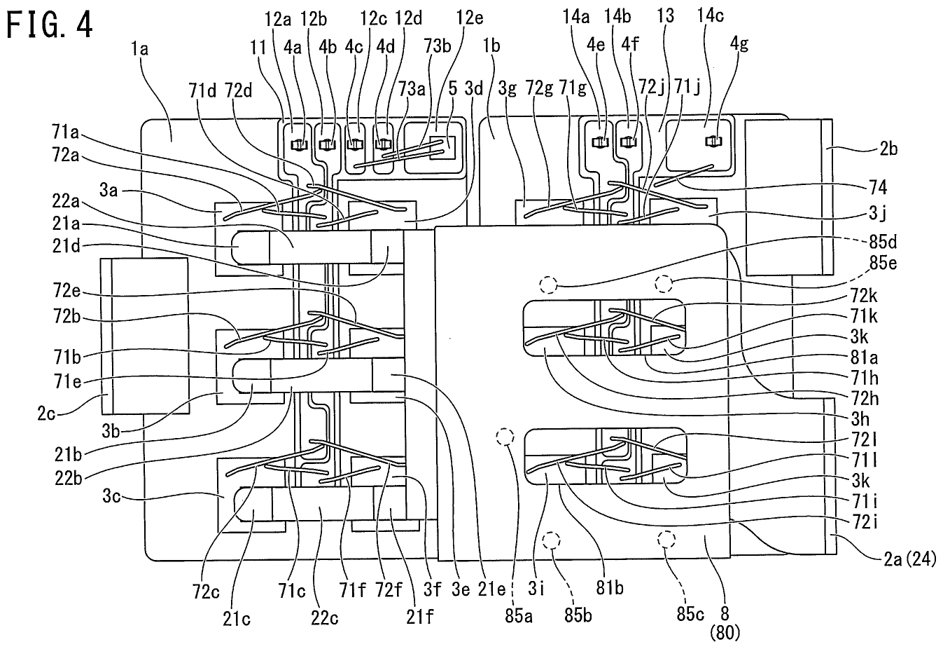

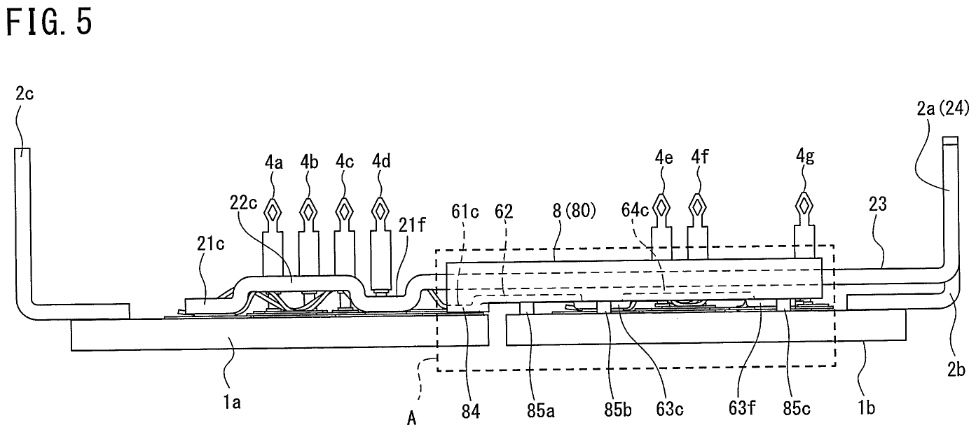

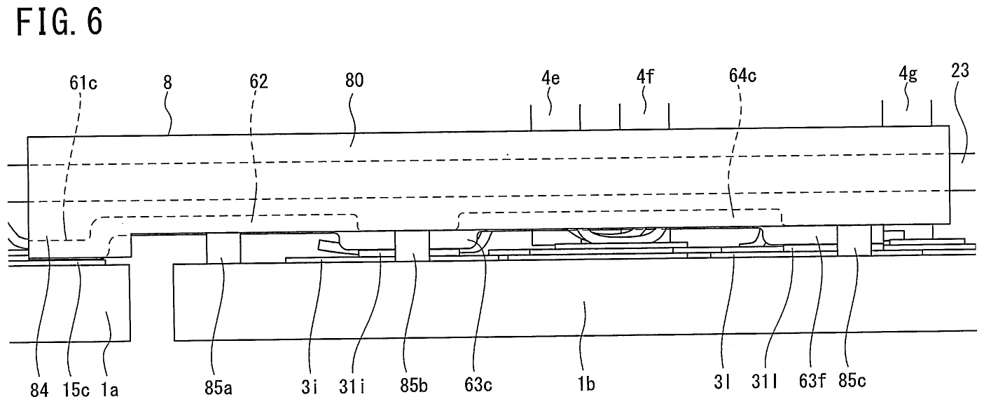

FIG. 3 is a perspective view illustrating the semiconductor device according to the first embodiment with the sealing resin 10 illustrated in FIG. 1 and FIG. 2 omitted. FIG. 4 is a plan view corresponding to FIG. 3, FIG. 5 is a side view corresponding to FIG. 3, and FIG. 6 is an enlarged side view of region A illustrated in FIG. 5.

As illustrated in FIG. 3 to FIG. 6, the semiconductor device according to the first embodiment includes a conductive substrate 1a and a conductive substrate 1b provided separately from each other. The conductive substrate 1a and the conductive substrate 1b each have a substantially rectangular planar pattern. The conductive substrate 1a and the conductive substrate 1b each include conductive material such as copper (Cu) and aluminum (Al). The respective bottom surfaces of the conductive substrate 1a and the conductive substrate 1b are exposed to the outside of the sealing resin 10 illustrated in FIG. 1 and FIG. 2.

The output terminal 2c is a plate-like member bent into an L-shape, and is bonded to the conductive substrate 1a via bonding material such as solder or sintered material or by direct bonding. The positive electrode terminal 2b is a plate-like member bent into an L-shape, and is bonded to the conductive substrate 1b via bonding material such as solder or sintered material or by direct bonding. The negative electrode terminal 2a is arranged next to the positive electrode terminal 2b, and includes an external connection part 24 which is a plate-like member bent into an L-shape. The negative electrode terminal 2a extends toward the output terminal 2c to elongate across the conductive substrate 1b to reach the conductive substrate 1a. The respective control terminals 4a to 4g are arranged parallel to each other and extend in a direction vertical to the respective top surfaces of the conductive substrate 1a and the conductive substrate 1b.

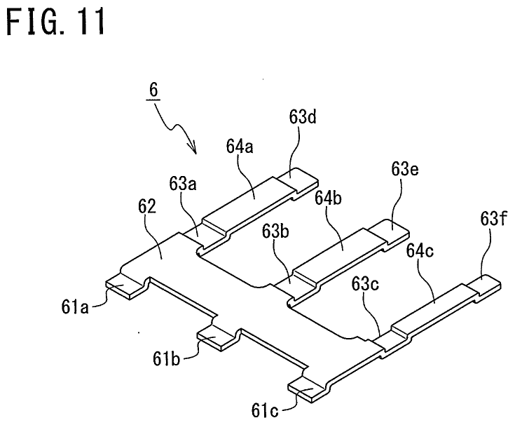

Although not illustrated in FIG. 3 or FIG. 4, a conductive member (also referred to as an “intermediate clip” or a “lead frame”) 6 illustrated in FIG. 11 is provided between the negative electrode terminal 2a and each of the conductive substrate 1a and the conductive substrate 1b. The conductive member 6 is provided to be separately opposed to a part of the negative electrode terminal 2a. A part of the negative electrode terminal 2a and a part of the conductive member 6 are covered with a resin member 8.

The negative electrode terminal 2a, the conductive member 6, and the resin member 8 are integrated together by integration molding, for example, so as to implement an integrated structure body (2b, 6, 8). The resin member 8 is provided so as to be partly interposed between the negative electrode terminal 2a and the conductive member 6. Integrating the negative electrode terminal 2a, the conductive member 6, and the resin member 8 together while keeping a gap between the negative electrode terminal 2a and the conductive member 6 by the interposition of the resin member 8, can exhibit a low inductance, ensure insulation properties, and allow void management (evaluation). Further, the provision of the negative electrode terminal 2a, the conductive member 6, and the resin member 8 as a single member can prevent an increase in cost derived from a complication of jigs or lead frames, so as to lead to a decrease in the number of manufacturing steps. The respective structures of the negative electrode terminal 2a, the conductive member 6, and the resin member 8 are described in detail below.

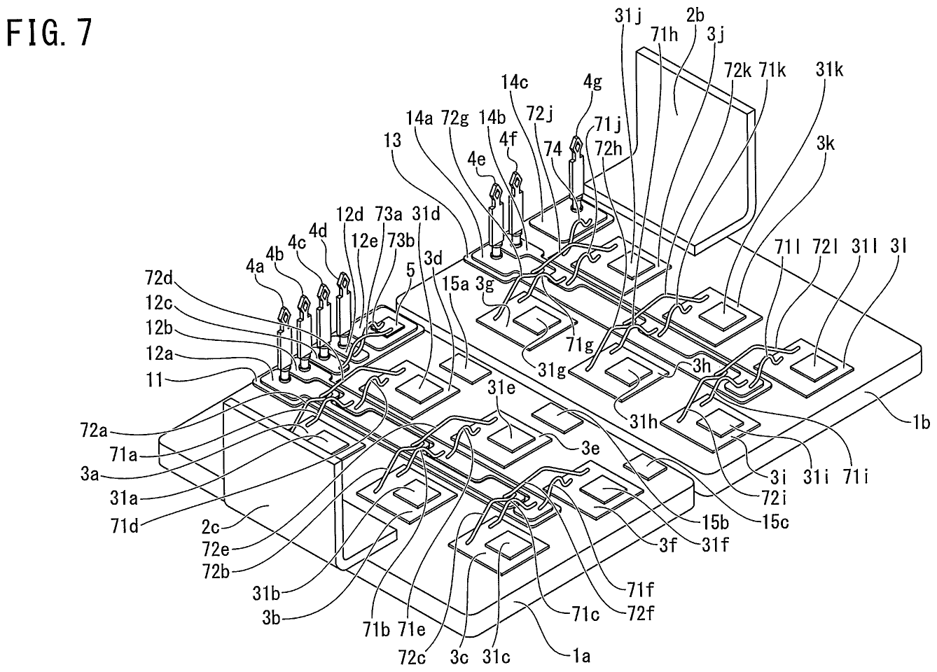

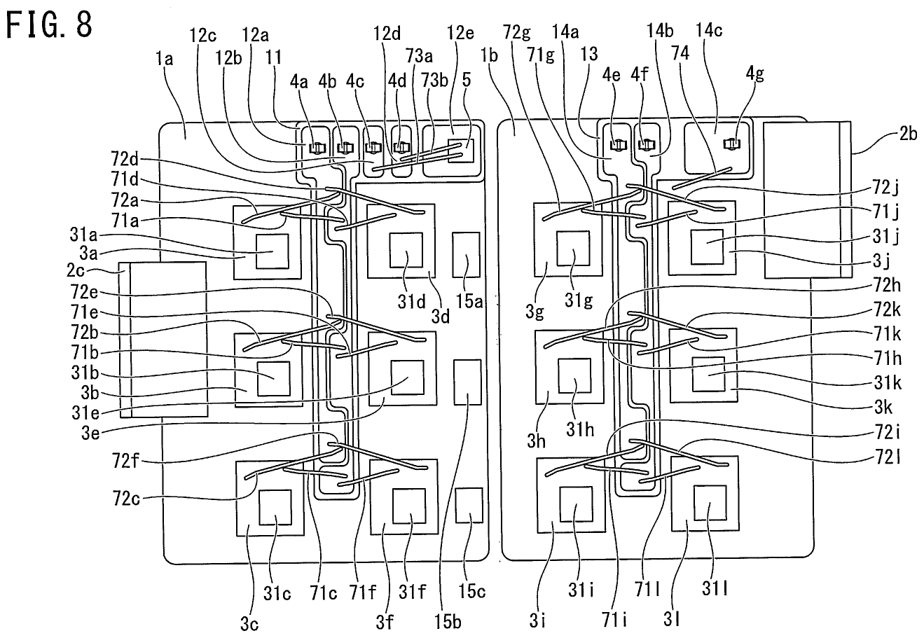

FIG. 7 is a perspective view illustrating the semiconductor device according to the first embodiment illustrated in FIG. 1 and FIG. 2 while omitting the sealing resin 10 and further omitting the integrated structure body (2a, 6, 8) implemented by the negative electrode terminal 2a, the conductive member 6, and the resin member 8. FIG. 8 is a plan view corresponding to FIG. 7.

As illustrated in FIG. 7 and FIG. 8, the semiconductor device according to the first embodiment includes a plurality of (six) power semiconductor elements (semiconductor chips) 3a to 3f provided on the top surface side of the conductive substrate 1a, and a plurality of (six) power semiconductor elements (semiconductor chips) 3g to 3l provided on the top surface side of the conductive substrate 1b. The respective semiconductor chips 3a to 3f are bonded onto the conductive substrate 1a via bonding material such as solder or sintered material. The semiconductor chips 3a to 3f are connected parallel to each other on the conductive substrate 1a so as to form a first raw and a second raw. The respective semiconductor chips 3g to 3l are bonded onto the conductive substrate 1b via bonding material such as solder or sintered material. The semiconductor chips 3g to 3l are connected parallel to each other on the conductive substrate 1b so as to form a first raw and a second raw.

The semiconductor device according to the first embodiment is illustrated with a 2-in-1 power semiconductor module including the semiconductor chips 3a to 3l that are each a MOSFET, in which two sets of six MOSFETs arranged in parallel are connected in series. The respective semiconductor chips 3a to 3f implement a lower arm of a half bridge circuit for one phase of a three-phase inverter circuit, and the respective semiconductor chips 3g to 3l implement an upper arm of the half bridge circuit. The semiconductor device according to the first embodiment is not limited to the 2-in-1 semiconductor module, and may be a 6-in-1 semiconductor module instead, for example.

The respective semiconductor chips 3a to 3l include a semiconductor substrate, a first main electrode (a drain electrode) provided on the bottom surface side of the semiconductor substrate, and second main electrodes (source electrodes) 31a to 31l and a control electrode (a gate electrode) provided on the top surface side of the semiconductor substrate. The respective drain electrodes of the semiconductor chips 3a to 3f are electrically connected to the conductive substrate 1a. The respective drain electrodes of the semiconductor chips 3g to 3l are electrically connected to the conductive substrate 1b.

The semiconductor substrate of the respective semiconductor chips 3a to 31 includes silicon (Si), silicon carbide (SiC), gallium nitride (GaN), or gallium oxide (Ga₂O₃), for example. The arranged positions and the number of the semiconductor chips 3a to 3l can be changed as appropriate. The respective semiconductor chips 3a to 31 may be a field-effect transistor (FET) such as a MOSFET, or may be an insulated gate bipolar transistor (IGBT), a reverse conductive IGBT (RC-IGBT) in which a diode is connected in antiparallel to an IGBT, a static induction (SI) thyristor, or a gate turn-off (GTO) thyristor.

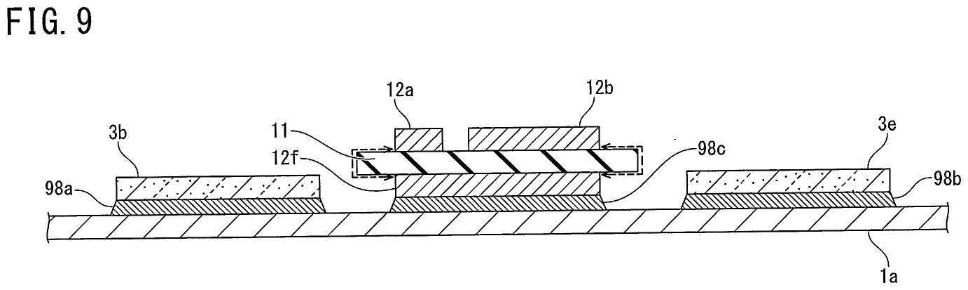

A printed wiring board (11, 12a to 12f) for control wiring is provided on the top surface side of the conductive substrate 1a. This printed wiring board is also referred to as a control wired substrate. The printed wiring board (11, 12a to 12f) includes an insulating layer 11, conductive layers 12a to 12e provided separately from each other on the top surface side of the insulating layer 11, and a conductive layer 12f (refer to FIG. 9) provided on the bottom surface side of the insulating layer 11 and having a smaller width than the insulating layer 11.

The insulating layer 11 has a first region extending in one direction (in the upper-lower direction in FIG. 8) along the respective semiconductor chips 3a to 3f, and a second region extending in the direction perpendicular to the first region (in the right-left direction in FIG. 8). While FIG. 7 and FIG. 8 illustrate the case in which the insulating layer 11 has a T-shaped planar pattern, the insulating layer 11 is not limited to this case, and may have an L-shaped planar pattern, for example. The respective conductive layers 12a to 12e are aligned on the second region of the insulating layer 11. The conductive layers 12a and 12b are each provided along both the first region and the second region of the insulating layer 11. The control terminals 4a to 4d are aligned respectively on the conductive layers 12a to 12d.

The insulating layer 11 is a ceramic plate mainly including aluminum oxide (Al₂O₃), aluminum nitride (AlN), silicon nitride (Si₃N₄), or boron nitride (BN), or a resin insulating layer including polymer material, for example. The resin insulating layer may be obtained such that glass fibers are impregnated with epoxy resin. The respective conductive layers 12a to 12f include copper (Cu) or aluminum (Al), for example.

FIG. 9 is a cross-sectional view illustrating a part of the printed wiring board (11, 12a to 12f) located between the semiconductor chip 3b and the semiconductor chip 3e in the packaged structure of the semiconductor device illustrated in FIG. 7 and FIG. 8. The semiconductor chip 3b is bonded to the top surface side of the conductive substrate 1a via bonding material 98a. The semiconductor chip 3e is bonded to the top surface side of the conductive substrate 1a via bonding material 98b. The conductive layer 12f of the printed wiring board (11, 12a to 12f) is bonded to the top surface side of the conductive substrate 1a via bonding material 98c. The bonding materials 98a to 98c as used herein can be solder or sintered material.

The conductive layer 12f has a smaller width than the insulating layer 11, so as to ensure a long creepage insulation distance between both side edges of the conductive layer 12f and the respective side edges of the conductive layers 12a and 12b along the end bottom surfaces, the side surfaces, and the end top surfaces of the insulating layer 11, as indicated by the broken lines. This structure thus can decrease a distance between the semiconductor chip 3b and the semiconductor chip 3e, as compared with a case in which the insulating layer 11 is directly deposited on the top surface of the conductive substrate la, since the end bottom surfaces and the end top surfaces of the insulating layer 11 overlap with each other. A structure in cross section of a printed wiring board (13, 14a, 14b) between the respective semiconductor chips 3h and 3k illustrated in FIG. 7 and FIG. 8 is the same as that of the printed wiring board (11, 12a to 12f), and overlapping explanations are not repeated below. Although not illustrated, a bottom surface of an insulating layer 13 of the printed wiring board (13, 14a, 14b) is also provided with a conductive layer, similar to the conductive layer 12f of the printed wiring board (11, 12a to 12f), having a narrower width than the insulating layer 13.

The insulating layer 11 and the conductive layer 12a are provided from the end part of the conductive substrate 1a to extend between the respective semiconductor chips 3a to 3c and the respective semiconductor chips 3d to 3f. The conductive layer 12a and the conductive layer 12b each have wider regions alternately arranged. The wider regions of the conductive layer 12a are electrically connected to part of the respective source electrodes 31a to 31f of the semiconductor chips 3a to 3f via control wires (bonding wires) 72a to 72f. The control terminal 4a is bonded to the conductive layer 12a via bonding material such as solder or sintered material. The control terminal 4a extends upward from the conductive layer 12a in the direction vertical to the top surface of the conductive layer 12a. The control terminal 4a applies control signals to the respective source electrodes 31a to 31f of the semiconductor chips 3a to 3f through the conductive layer 12a and the respective bonding wires 72a to 72f.

The conductive layer 12b is arranged parallel to the conductive layer 12a from the end of the conductive substrate 1a to extend between the respective semiconductor chips 3a to 3c and the respective semiconductor chips 3d to 3f. The wider regions of the conductive layer 12b are electrically connected to the gate electrodes (not illustrated) of the respective semiconductor chips 3a to 3f via control wires (bonding wires) 71a to 71f. The control terminal 4b is bonded to the conductive layer 12b via bonding material such as solder or sintered material. The control terminal 4b extends upward from the conductive layer 12b in the direction vertical to the top surface of the conductive layer 12b. The control terminal 4b is electrically conductive to the respective gate electrodes of the semiconductor chips 3a to 3f via the respective bonding wires 71a to 71f and the conductive layer 12b. A voltage is applied to the control terminal 4a, and a voltage in which a threshold voltage value or greater of the respective semiconductor chips 3a to 3f is added to the voltage value of the control terminal 4a is applied to the control terminal 4b when the respective semiconductor chips 3a to 3f are turned ON.

A temperature detection chip 5 provided with two electrodes (not illustrated) on the surface is bonded to the conductive layer 12e via bonding material such as solder or sintered material.

The control terminal 4c is bonded to the conductive layer 12c via bonding material such as solder or sintered material. The control terminal 4c extends upward from the conductive layer 12c in the direction vertical to the top surface of the conductive layer 12c. The conductive layer 12c is connected to one of the electrodes of the temperature detection chip 5 via a control wire (a bonding wire) 73a.

The control terminal 4d is bonded to the conductive layer 12d via bonding material such as solder or sintered material. The control terminal 4d extends upward from the conductive layer 12d in the direction vertical to the top surface of the conductive layer 12d. The conductive layer 12d is connected to the other electrode of the temperature detection chip 5 via a control wire (a bonding wire) 73b.

The respective control terminals 4c and 4d transmit temperature detection signals from the temperature detection chip 5 to the outside through the bonding wires 73a and 73b and the conductive layers 12c and 12d.

The top surface of the conductive substrate 1a on one side closer to the conductive substrate 1b is provided with pads 15a to 15c. The pads 15a to 15c are bonded to the top surface of the conductive substrate 1a via bonding material such as solder or sintered material. The respective pads 15a to 15c include conductive material such as copper (Cu) and aluminum (Al). The respective pads 15a to 15c may be provided integrally with the conductive substrate 1a.

The printed wiring board for control wiring (13, 14a to 14c) is provided on the top surface side of the conductive substrate 1b. The printed wiring board (13, 14a to 14c) includes the insulating layer 13, and conductive layers 14a to 14c provided separately from each other on the top surface side of the insulating layer 13. The insulating layer 13 can include the same material as the insulating layer 11, and the conductive layers 14a to 14c can include the same material as the conductive layers 12a to 12e.

The insulating layer 13 has a first region extending in one direction (in the upper-lower direction in FIG. 8) along the respective semiconductor chips 3g to 31, and a second region extending in the direction perpendicular to the first direction (in the right-left direction in FIG. 8). While FIG. 7 and FIG. 8 illustrate the case in which the insulating layer 13 has a T-shaped planar pattern, the present embodiment is not limited to this case, and the insulating layer 13 may have an L-shaped planar pattern, for example. The respective conductive layers 14a to 14c are aligned on the second region of the insulating layer 13. The conductive layers 14a and 14b are each provided along both the first region and the second region of the insulating layer 13. The control terminals 4e to 4g are aligned respectively on the conductive layers 14a to 14c.

The insulating layer 13 and the conductive layer 14a are provided from the end part of the conductive substrate 1b to extend between the respective semiconductor chips 3g to 3i and the respective semiconductor chips 3j to 3l. The conductive layer 14a and the conductive layer 14b each have wider regions alternately arranged. The wider regions of the conductive layer 14a are electrically connected to part of the respective source electrodes 31g to 311 of the semiconductor chips 3g to 3l via control wires (bonding wires) 72g to 72l. The control terminal 4c is bonded to the conductive layer 14a via bonding material such as solder or sintered material. The control terminal 4e extends upward from the conductive layer 14a in the direction vertical to the top surface of the conductive layer 14a. The control terminal 4e applies control signals to the respective source electrodes 31g to 311 of the semiconductor chips 3g to 3l through the conductive layer 14a and the respective bonding wires 72g to 72l.

The conductive layer 14b is arranged parallel to the conductive layer 14a from the end of the conductive substrate 1b to extend between the respective semiconductor chips 3g to 3i and the respective semiconductor chips 3j to 3l. The wider regions of the conductive layer 14b are electrically connected to the gate electrodes (not illustrated) of the respective semiconductor chips 3g to 3l via control wires (bonding wires) 71g to 71l. The control terminal 4f is bonded to the conductive layer 14b via bonding material such as solder or sintered material. The control terminal 4f extends upward from the conductive layer 14b in the direction vertical to the top surface of the conductive layer 14b. The control terminal 4f is electrically conductive to the respective gate electrodes of the semiconductor chips 3g to 3l via the respective bonding wires 71g to 711 and the conductive layer 14b. A voltage is applied to the control terminal 4e, and a voltage in which a threshold voltage value or greater of the respective semiconductor chips 3g to 31 is added to the voltage value of the control terminal 4e is applied to the control terminal 4f when the respective semiconductor chips 3g to 3l are turned ON.

The conductive layer 14c is connected to the conductive substrate 1b via a control wire (a bonding wire) 74. The control terminal 4g is bonded to the conductive layer 14c via bonding material such as solder or sintered material. The control terminal 4g extends upward from the conductive layer 14c in the direction vertical to the top surface of the conductive layer 14c. The control terminal 4g transmits signals of current flowing through the respective drain electrodes of the semiconductor chips 3g to 3l via the bonding wire 74 and the conductive layer 14c.

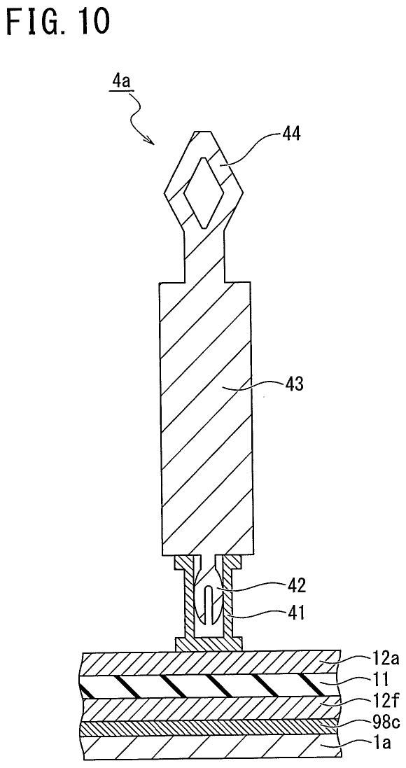

FIG. 10 is a cross-sectional view illustrating the control terminal 4a illustrated in FIG. 7 and FIG. 8. The control terminal 4a is provided on the top surface side of the conductive substrate 1a with the conductive layer 12f, the insulating layer 11, and the conductive layer 12a of the printed wiring board (11, 12a to 12f) interposed. The control terminal 4a includes a support part 41 and an extending part (42, 43, 44) supported by the support part 41. The support part 41 is a cylindrical sleeve having an opening, for example. The support part 41 is bonded to the conductive layer 12a via bonding material such as solder or sintered material.

The extending part (42, 43, 44) is a press-fit pin, for example. The extending part (42, 43, 44) includes a first end part (a lower end part) 42 supported by the support part 41, a middle part 43 integrated with the first end part 42, and a second end part (an upper end part) 44 integrated with the middle part 43. The first end part 42 may have any shape that can be press-fitted and fixed to the opening of the support part 41. The middle part 43 extends in the direction vertical to the top surface of the conductive substrate 1a. The middle part 43 may have any shape, such as a plate-like shape, a pin-like shape, a stick-like shape, a cylindrical shape, or a polygonal columnar shape. The second end part 44 has a wide part that can be press-fitted to a penetration hole of an external member. The second end part 44 may have any shape that can be electrically connected to the external member. The respective control terminals 4b to 4g illustrated in FIG. 7 and FIG. 8 have the same structure as the control terminal 4a as illustrated in FIG. 10.

FIG. 11 is a perspective view illustrating the conductive member 6 implementing a part of the integrated structure body (2a, 6, 8). As illustrated in FIG. 11, the conductive member 6 includes pad bonding parts 61a to 61c, a connection part 62 connected to the pad bonding parts 61a to 61c, chip bonding parts 63a to 63c connected to the connection part 62, connection parts 64a to 64c connected to the chip bonding parts 63a to 63c, and chip bonding parts 63d to 63f connected to the connection parts 64a to 64c. The pad bonding parts 61a to 61c and the chip bonding parts 63a to 63f are bent to project downward from the connection part 62 and the connection parts 64a to 64c. The respective connection parts 64a to 64c have a stripe-shaped planar pattern extending separately parallel to each other.

At least the bottom surfaces of the respective pad bonding parts 61a to 61c are exposed to the outside of the resin member 8 illustrated in FIG. 3 to FIG. 6. The pad bonding parts 61a to 61c are bonded to the pads 15a to 15c provided on the top surface side of the conductive substrate 1a illustrated in FIG. 7 and FIG. 8 via bonding material such as solder or sintered material. The connection part 62 and the connection parts 64a to 64c are covered with the resin member 8 illustrated in FIG. 3 to FIG. 6. At least the bottom surfaces of the respective chip bonding parts 63a to 63f are exposed to the outside of the resin member 8 illustrated in FIG. 3 to FIG. 6. The chip bonding parts 63a to 63f are bonded to the source electrodes 31g to 311 of the semiconductor chips 3g to 31 illustrated in FIG. 7 and FIG. 8 via bonding material such as solder or sintered material.

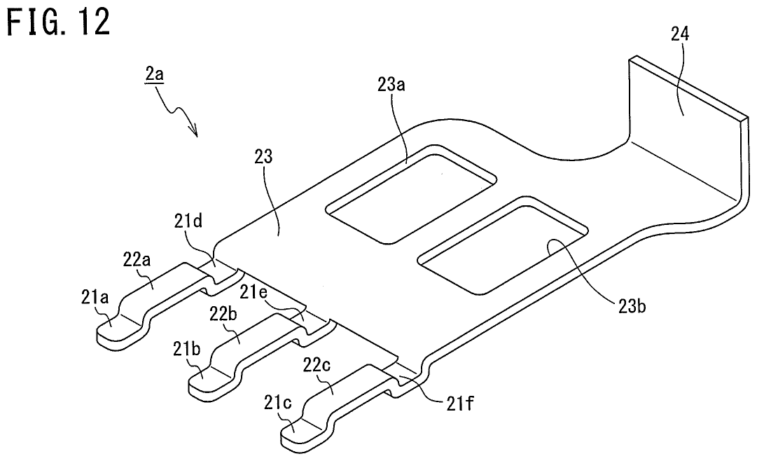

FIG. 12 is a perspective view illustrating the negative electrode terminal 2a implementing a part of the integrated structure body (2a, 6, 8). As illustrated in FIG. 12, the negative electrode terminal 2a includes chip bonding parts 21a to 21c, connection parts 22a to 22c connected to the chip bonding parts 21a to 21c, chip bonding parts 21d to 21f connected to the connection parts 22a to 22c, a connection part 23 connected to the chip bonding parts 21d to 21f, and an external connection part 24 connected to the connection part 23. The chip bonding parts 21a to 21f, the connection parts 22a to 22c, and the external connection part 24 are exposed to the outside of the resin member 8 illustrated in FIG. 3 to FIG. 6. A part of the connection part 23 is exposed to the outside of the resin member 8 illustrated in FIG. 3 to FIG. 6, while the other part of the connection part 23 is covered with the resin member 8.

The chip bonding parts 21a to 21f illustrated in FIG. 12 are bent to project downward from the connection parts 22a to 22c. The chip bonding parts 21a to 21f are bonded to the source electrodes 31a to 31f of the semiconductor chips 3a to 3f illustrated in FIG. 7 and FIG. 8 via bonding material such as solder or sintered material. The respective connection parts 22a to 22c have a stripe-shaped planar pattern extending separately parallel to each other.

The connection part 23 has a substantially rectangular shape. The connection part 23 is arranged to be opposed to the pad bonding parts 61a to 61c, the connection part 62, the chip bonding parts 63a to 63f, and the connection parts 64a to 64c of the conductive member 6 illustrated in FIG. 11. The connection part 23 is provided with openings 23a and 23b penetrating from the top surface to the bottom surface of the connection part 23. The openings 23a and 23b each have a substantially rectangular planar pattern. The opening 23a is positioned to overlap with a space between the respective connection parts 64a and 64b illustrated in FIG. 11. The opening 23b is positioned to overlap with a space between the respective connection parts 64b and 64c illustrated in FIG. 11.

The opening 23a is positioned to overlap with a control wiring region in a plana view including the bonding wires 71h, 71k, 72h, and 72k connected to the semiconductor chips 3h and 3k illustrated in FIG. 7 and FIG. 8. The opening 23b is positioned to overlap with a control wiring region including the bonding wires 71i, 711, 72i, and 72l connected to the semiconductor chips 3i and 3l illustrated in FIG. 7 and FIG. 8.

Instead of the negative electrode terminal 2a itself, the external connection part 24 that is a part of the negative electrode terminal 2a may be referred to as a “negative electrode terminal”, and the other parts of the negative electrode terminal 2a other than the external connection part 24, which are the chip bonding parts 21a to 21c, the connection terminals 22a to 22c, the chip bonding parts 21d to 21f, and the connection part 23 may be collectively referred to as a “lead frame” integrated with the “negative electrode terminal”.

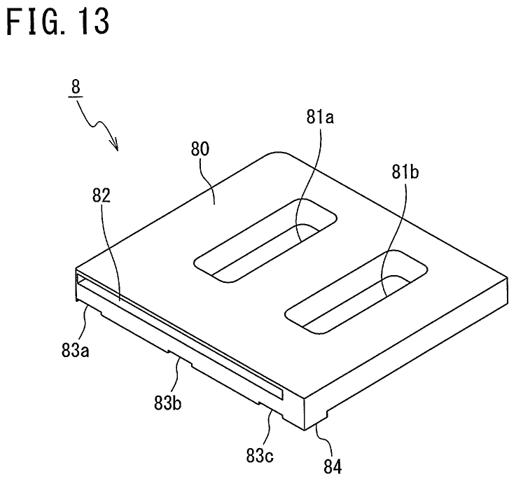

FIG. 13 is a perspective view illustrating the resin member 8 implementing a part of the integrated structure body (2a, 6, 8). As illustrated in FIG. 13, the resin member 8 includes a body part 80 having a substantially cuboidal outline. The side surface of the body part 80 is provided with an opening 82 and openings 83a to 83c. The connection part 23 of the negative electrode terminal 2a is partly exposed to the opening 82. The pad bonding parts 61a to 61c of the conductive member 6 are exposed to the openings 83a to 83c. The body part 80 is further provided with openings 81a and 81b penetrating from the top surface to the bottom surface of the body part 80. The openings 81a and 81b are positioned to respectively overlap with the openings 23a and 23b of the negative electrode terminal 2a illustrated in FIG. 12.

The opening 81a of the resin member 8 is positioned to overlap with the control wiring region including the bonding wires 71h, 71k, 72h, and 72k connected to the semiconductor chips 3h and 3k in the planar view when the integrated structure body (2a, 6, 8) is provided on the top surface side of the respective conductive substrates 1a and 1b, as illustrated in FIG. 3 and FIG. 4. The opening 81b is positioned to overlap with the control wiring region including the bonding wires 71i, 71i, 72i, and 72i connected to the semiconductor chips 3i and 3l.

As illustrated in FIG. 4 to FIG. 6, the bottom surface of the body part 80 is provided with a support part 84 and support parts 85a to 85e. FIG. 4 schematically indicates the support parts 85a to 85e hidden under the body part 80 by the broken lines. The support part 84 and the support parts 85a to 85e are provided integrally with the body part 80. The support part 84 is positioned on the top surface side of the conductive substrate 1a. The respective support parts 85a to 85e are positioned on the top surface side of the conductive substrate 1b. The support parts 85a to 85e each have a cylindrical shape, for example, but the shape is not limited to the case as illustrated. The arranged positions and the number of the support parts 85a to 85e can be changed as appropriate.

The provision of the support part 84 and the support parts 85a to 85e on the bottom surface side of the body part 80 can avoid an inclination of the integrated structure body (2a, 6, 8) including the chip bonding parts 21a to 21f of the negative electrode terminal 2a and the chip bonding parts 63a to 63f of the conductive member 6 when the chip bonding parts 21a to 21f and the chip bonding parts 63a to 63f are bonded to the source electrodes of the semiconductor chips 3a to 3l by solder, so as to suppress an increase in height of the integrated structure body (2a, 6, 8).

The surface of the resin member 8 may be roughed by crepe processing or the like. The roughening of the surface of the resin member 8 can prevent a separation between the resin member 8 and the sealing resin 10 so as to improve the adhesion. The roughening processing may be executed either partly or entirely on the surface of the resin member 8.

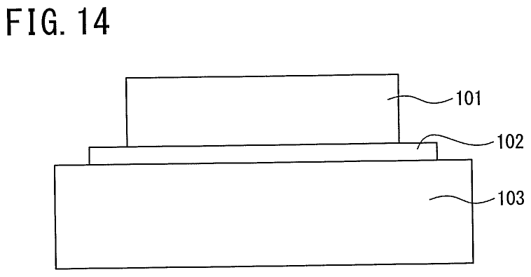

FIG. 14 is a schematic cross-sectional view illustrating a packaged structure of a semiconductor device 101 according to the first embodiment. The semiconductor device 101 corresponds to the semiconductor device illustrated in FIG. 1 and FIG. 2, and the respective bottom surface sides of the conductive substrates 1a and 1b are exposed on the bottom surface of the semiconductor device 101. A cooling device (a base) 103 is provided on the bottom surface side of the semiconductor device 101 with a sheet-like resin layer (a resin sheet) 102 interposed.

The resin sheet 102 has functions of ensuring the properties of insulation and bonding between the semiconductor device 101 and the cooling device 103 while releasing heat from the semiconductor devices 101 toward the cooling device 103. The resin sheet 102 as used herein can include epoxy resin, for example. The cooling device 103 as used herein can include material such as copper (Cu), aluminum (Al), composite material (AlSiC) of Al and silicon carbide, and composite material (MgSiC) of magnesium (Mg) and silicon carbide.

The packaged structure of the semiconductor device 101 can integrate the functions of the insulation, the bonding, and the heat release into the resin sheet 102, so as to reduce costs, as compared with a case in which the insulated circuit substrate is bonded to the cooling device by soldering.

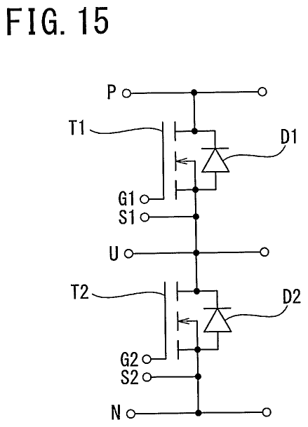

FIG. 15 is an equivalent circuit diagram of the semiconductor device according to the first embodiment. As illustrated in FIG. 15, the semiconductor device according to the first embodiment implements a part of a three-phase bridge circuit. A drain electrode of a transistor T1 on the upper-arm side is connected to a positive electrode terminal P, and a source electrode of a transistor T2 on the lower-arm side is connected to a negative electrode terminal N. A source electrode of the transistor T1 and a drain electrode of the transistor T2 are connected to an output terminal U and an auxiliary source terminal S1. An auxiliary source terminal S2 is connected to the source electrode of the transistor T2. Gate control terminals G1 and G2 are connected to gate electrodes of the respective transistors T1 and T2. Body diodes D1 and D2 each serving as a freewheeling diode (FWD) are internally connected in antiparallel to the transistors T1 and T2.

The output terminal U, the positive electrode terminal P, and the negative electrode terminal N illustrated in FIG. 15 respectively correspond to the output terminal 2c, the positive electrode terminal 2b, and the negative electrode terminal 2a illustrated in FIG. 7 and FIG. 8. The transistor T1 and the body diode D1 illustrated in FIG. FIG. 15 correspond to the semiconductor chips 3g to 3l illustrated in FIG. 7 and FIG. 8. The transistor T2 and the body diode D2 illustrated in FIG. FIG. 15 correspond to the semiconductor chips 3a to 3f illustrated in FIG. 7 and FIG. 8. The gate control terminals G1 and G2 illustrated in FIG. 15 correspond to the control terminals 4b and 4f illustrated in FIG. 7 and FIG. 8. The auxiliary source terminals S1 and S2 illustrated in FIG. 15 correspond to the control terminals 4a and 4e illustrated in FIG. 7 and FIG. 8.

An example of manufacturing the semiconductor device according to the first embodiment is described below. As illustrated in FIG. 7 and FIG. 8, the output terminal 2c, the semiconductor chips 3a to 3f, the printed wiring board (11, 12a to 12e), and the pads 15a to 15c are bonded to the top surface of the conductive substrate 1a via bonding material such as solder or sintered material. Further, the control terminals 4a to 4d and the temperature detection chip 5 are bonded to the top surface of the printed wiring board (11, 12a to 12e) via bonding material such as solder or sintered material. At this point, the support part 41 is bonded to the top surface of the conductive layer 12a via bonding material such as solder or sintered material, as illustrated in FIG. 10. The first end part 42 of the extending part (42, 43, 44) is then press-fitted into the support part 41 so that the control terminal 4a is arranged to extend upward on the top surface of the conductive layer 12 in the vertical direction. The respective control terminals 4b to 4d are arranged in the same manner as the control terminal 4a. Further, the gate electrodes (not illustrated) of the semiconductor chips 3a to 3f and the conductive layer 12b of the printed wiring board 11 are connected to each other via the bonding wires 71a to 71f for gate signal, the source electrodes (not illustrated) of the semiconductor chips 3a to 3f and the conductive layer 12a of the printed wiring board 11 are connected to each other via the bonding wires 72a to 72f for auxiliary source, one of the electrodes of the temperature detection chip 5 and the conductive layer 12c of the printed wiring board 11 are connected to each other via the bonding wire 73a for temperature signal, and the other electrode of the temperature detection chip 5 and the conductive layer 12d of the printed wiring board 11 are connected to each other via the bonding wire 73b for temperature detection.

Similarly, as illustrated in FIG. 7 and FIG. 8, the positive electrode terminal 2b, the semiconductor chips 3g to 31, and the printed wiring board (13, 14a to 14c) are bonded to the top surface of the conductive substrate 1b via bonding material such as solder or sintered material. Further, the control terminals 4e to 4g are bonded to the top surface of the printed wiring board (13, 14a to 14c) via bonding material such as solder or sintered material. The control terminals 4e to 4g are also arranged to extend upward on the top surfaces of the conductive layers 14a to 14c in the vertical direction, as in the case of the control terminal 4a. Further, the gate electrodes (not illustrated) of the semiconductor chips 3g to 3l and the conductive layer 14b of the printed wiring board 13 are connected to each other via the bonding wires 71g to 711 for gate signal, and the source electrodes (not illustrated) of the semiconductor chips 3g to 3l and the conductive layer 14a of the printed wiring board 13 are connected to each other via the bonding wires 72g to 721 for auxiliary source. The conductive substrate 1b and the conductive layer 14c of the printed wiring board 13 are further connected to each other via the bonding wire 74.

Next, the conductive member 6 illustrated in FIG. 11, the negative electrode terminal 2a illustrated in FIG. 12, and the resin member 8 illustrated in FIG. 13 are formed together by integral molding with a metal die so as to prepare the integrated structure body (2a, 6, 8).

Next, as illustrated in FIG. 3 to FIG. 6, the conductive substrate 1a to which the semiconductor chips 3a to 3f and the like are bonded and the conductive substrate 1b to which the semiconductor chips 3g to 3l and the like are bonded are opposed to the integrated structure body (2a, 6, 8). The chip bonding parts 21a to 21f of the negative electrode terminal 2a serving as a constituent member of the integrated structure body (2a, 6, 8) are bonded to the source electrodes 31a to 31f of the semiconductor chips 3a to 3f via bonding material such as solder or sintered material. Further, the chip bonding parts 63a to 63f of the conductive member 6 serving as a constituent member of the integrated structure body (2a, 6, 8) are bonded to the source electrodes 31g to 311 of the semiconductor chips 3g to 3l via bonding material such as solder or sintered material. Further, the pad bonding parts 61a to 61c of the conductive member 6 are bonded to the pads 15a to 15c on the top surface side of the conductive substrate 1a via bonding material such as solder or sintered material.

Thereafter, the respective semiconductor chips 3a to 3l and the like are sealed with the sealing resin 10 by transfer molding, as illustrated in FIG. 1. The semiconductor device according to the first embodiment is thus completed.

The semiconductor device according to the first embodiment has the configuration including the integrated structure body (2a, 6, 8) implemented by the negative electrode terminal 2a, the conductive member 6, and the insulating member 8 formed integrally with each other so as to provide a three-dimensional main wired circuit, and further including the control wired circuit implemented by the printed wiring board (11, 12a to 12e) and the printed wiring board (13, 14a, 14b) for control wiring provided separately from each other.

This configuration can decrease the wiring area, so as to achieve a reduction in chip size and cost and further ensure the low inductance properties, as compared with a conventional semiconductor device in which semiconductor chips are mounted on a circuit pattern of an insulated circuit substrate so that the semiconductor chips and the circuit pattern of the insulated circuit substrate are electrically connected to each other via lead frames and bonding wires.

Further, the direct deposition of the control terminals 4a to 4g on the printed wiring board (11, 12a to 12e) and the printed wiring board (13, 14a to 14c) provided on the conductive substrates 1a and 1b so as to extend upward, can decrease in size of the semiconductor device and further contribute to the strong bonding of the control terminals 4a to 4g to the printed wiring board (11, 12a to 12e) and the printed wiring board (13, 14a to 14c), as compared with a case in which the control terminals 4a to 4g are connected to the printed wiring board (11, 12a to 12e) and the printed wiring board (13, 14a to 14c) via bonding wires and lead frames.

Further, this configuration can ensure the reliability of the connection parts and facilitate the inspection, so as to contribute to a reduction in cost, as compared with a conventional semiconductor device with a configuration in which printed wiring boards are arranged over semiconductor chips provided on an insulated circuit substrate so that the semiconductor chips and the printed wiring board are electrically connected to each other via pin terminals. In addition, this configuration does not need to consider a problem of a warp or thermal deformation of the printed wiring boards, so as to improve packaging performance and reliability, facilitating the entire handling accordingly.

Further, the semiconductor device according to the first embodiment having the configuration as described above does not need to use a casing for surrounding the insulated circuit substrate to inject resin by potting to seal the insulated circuit substrate, so as to achieve a reduction in space, a decrease in the number of the manufacturing steps, and a reduction in cost, as compared with the conventional semiconductor device using such a casing.

The semiconductor device according to the first embodiment with the configuration described above can exhibit the wiring technique that contributes to a reduction in cost and facilitates the manufacturing process without use of complicated component-positioning-accuracy control technique, and can also keep the heat-releasing performance, so as to achieve the low-inductance characteristics capable of maximizing the switching performance of the semiconductor chips including silicon carbide (SiC). The semiconductor device according to the first embodiment with the configuration as described above can exhibit the great effects particularly on the decrease in the wiring areas when required to be equipped with a large number of small semiconductor chips including SiC arranged in parallel in order to reduce costs.

### Second Embodiment

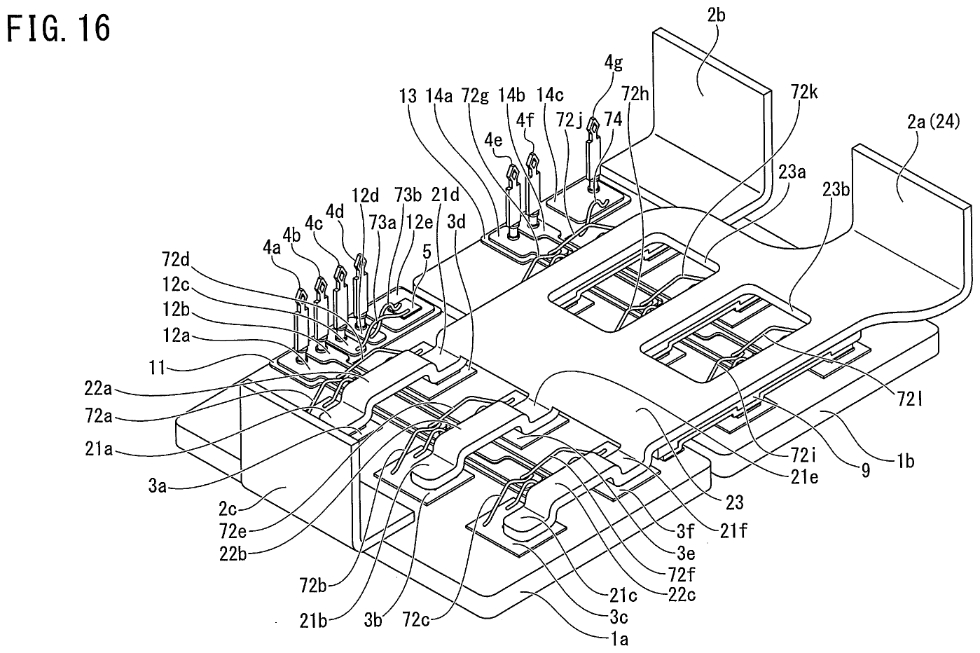

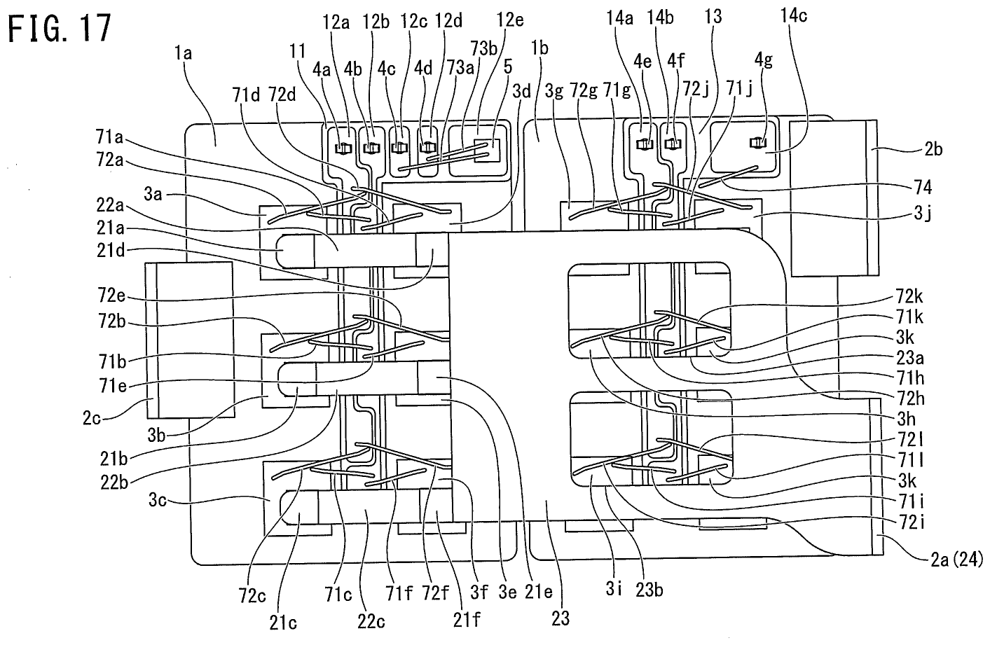

A semiconductor device according to a second embodiment has an external appearance similar to that of the semiconductor device according to the first embodiment illustrated in FIG. 1 and FIG. 2. FIG. 16 is a perspective view illustrating the semiconductor device according to the second embodiment while omitting the sealing resin 10 illustrated in FIG. 1 and FIG. 2. FIG. 17 is a plan view corresponding to FIG. 16. The semiconductor device according to the second embodiment includes printed wiring boards common to those of the semiconductor device according to the first embodiment.

As illustrated in FIG. 16 and FIG. 17, the semiconductor device according to the second embodiment differs from the semiconductor device according to the first embodiment in including a resin member 9 arranged to be interposed between the negative electrode terminal 2a and the conductive member 6. The semiconductor device according to the second embodiment has a laminated structure body (2a, 6, 9) including the negative electrode terminal 2a, the conductive member 6, and the resin member 9. The negative electrode terminal 2a and the conductive member 6 implementing the laminated structure body (2a, 6, 9) each have a structure common to that of the negative electrode terminal 2a illustrated in FIG. 12 and the conductive member 6 illustrated in FIG. 11.

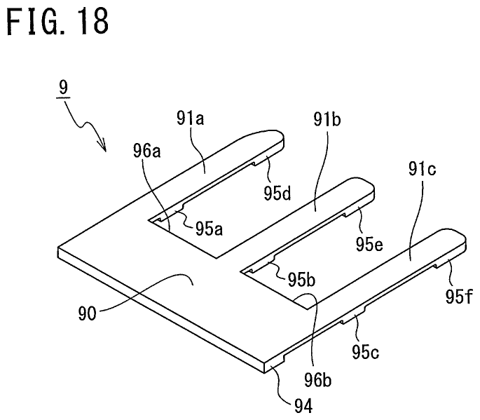

FIG. 18 is a perspective view illustrating the resin member 9 implementing a part of the laminated structure body (2a, 6, 9). As illustrated in FIG. 18, the resin member 9 includes a flat part 90, and stripe parts 91a to 91c connected to the flat part 90. The flat part 90 is positioned to be interposed between the connection part 62 of the conductive member 6 illustrated in FIG. 11 and the connection part 23 of the negative electrode terminal 2a illustrated in FIG. 12. The bottom surface of the flat part 90 is provided with a projection 94. The projection 94 is fitted to the respective pad bonding parts 61a to 61c of the conductive member 6 bent downward illustrated in FIG. 11. The provision of the projection 94 is optional.

The stripe part 91a is positioned between the chip bonding part 63a, the connection part 64a, and the chip bonding part 63d of the conductive member 6 illustrated in FIG. 11 and the stripe part of the connection part 23 located at the edge of the negative electrode terminal 2a toward the opening 23a illustrated in FIG. 12. The bottom surface of the stripe part 91a is provided with projections 95a and 95d. The projections 95a and 95d are fitted to the chip bonding parts 63a and 63d of the conductive member 6 bent downward illustrated in FIG. 11.

The stripe part 91b is positioned between the chip bonding part 63b, the connection part 64b, and the chip bonding part 63e of the conductive member 6 illustrated in FIG. 11 and the middle stripe part located between the respective openings 23a and 23b of the connection part 23 of the negative electrode terminal 2a illustrated in FIG. 12. The bottom surface of the stripe part 91b is provided with projections 95b and 95e. The projections 95b and 95e are fitted to the chip bonding parts 63b and 63e of the conductive member 6 bent downward illustrated in FIG. 11.

The stripe part 91c is positioned between the chip bonding part 63c, the connection part 64c, and the chip bonding part 63f of the conductive member 6 illustrated in FIG. 11 and the stripe part of the connection part 23 located at the edge of the negative electrode terminal 2a toward the opening 23b illustrated in FIG. 12. The bottom surface of the stripe part 91b is provided with projections 95c and 95f. The projections 95c and 95f are fitted to the chip bonding parts 63c and 63f of the conductive member 6 bent downward illustrated in FIG. 11.

The space between the respective stripe parts 91a and 91b is located to overlap with the space between the respective connection parts 64a and 64b of the conductive member 6 illustrated in FIG. 11 and also overlap with the opening 23a of the connection part 23 of the negative electrode terminal 2a illustrated in FIG. 12. The space between the respective stripe parts 91b and 91c is located to overlap with the space between the respective connection parts 64b and 64c of the conductive member 6 illustrated in FIG. 11 and also overlap with the opening 23b of the connection part 23 of the negative electrode terminal 2a illustrated in FIG. 12.

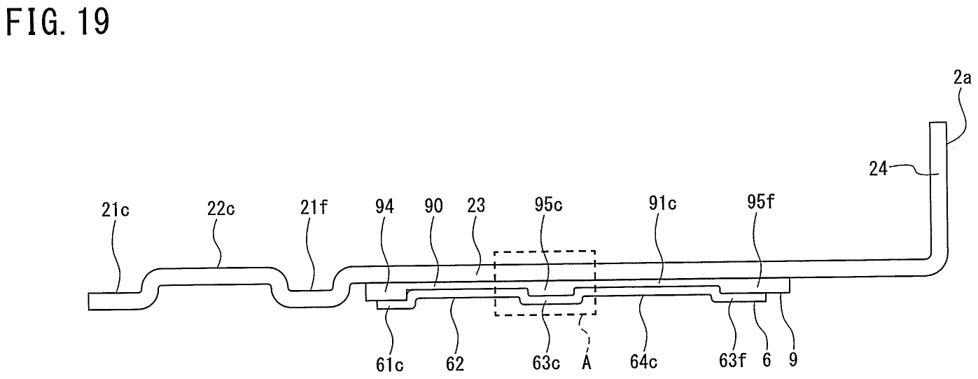

FIG. 19 is a cross-sectional view illustrating the laminated structure body (2a, 6, 9). As illustrated in FIG. 19, the top surface sides of the chip bonding parts 63c and 63f of the conductive member 6 are in contact with the projections 95c and 95f of the resin member 9. Similarly, the top surface sides of the chip bonding parts 63a, 63b, 63d, and 63e of the conductive member 6 are in contact with the projections 95a, 95b, 95d, and 95e of the resin member 9. As illustrated in FIG. 19, the respective top surface sides of the flat part 90 and the stripe part 91c of the resin member 9 are in contact with the bottom surface of the connection part 23 of the negative electrode terminal 2a. Similarly, the respective top surface sides of the stripe parts 91a and 91b of the resin member 9 are in contact with the bottom surface of the connection part 23 of the negative electrode terminal 2a.

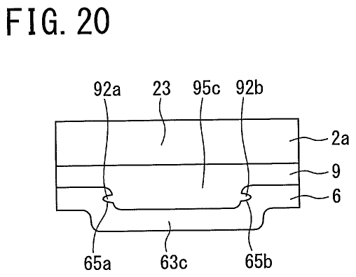

FIG. 20 is an enlarged side view of region A indicated by the broken line surrounding the circumference of the projection 95c of the resin member 9 illustrated in FIG. 19. The side surfaces of the projection 95c of the resin member 9 are provided with engagement parts (projections) 92a and 92b. The bent parts of the chip bonding part 63c of the conductive member 6 are provided with engagement parts (recesses) 65a and 65b. The projections 92a and 92b of the resin member 9 and the recesses 65a and 65b of the conductive member 6 are engaged with (fitted to) each other so as to fix the resin member 9 and the conductive member 6 together.

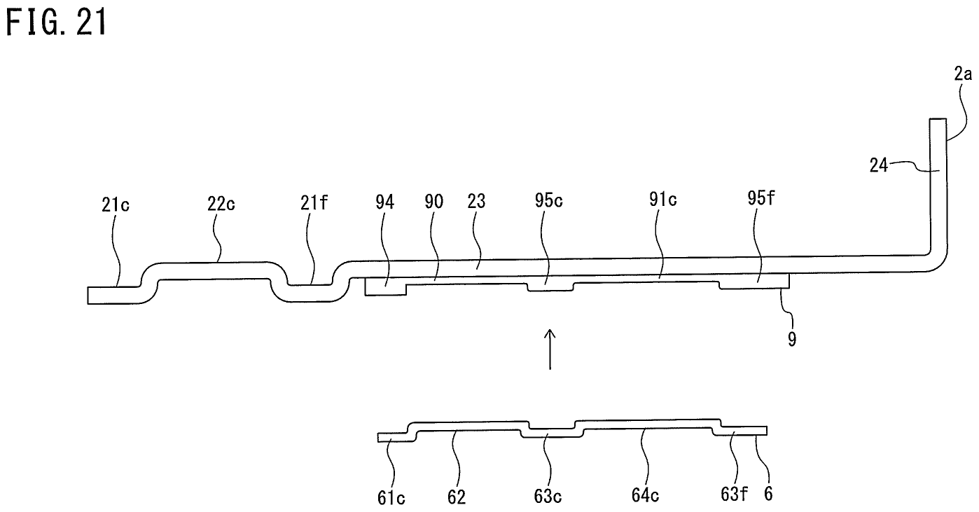

FIG. 21 is a view illustrating an example of a method of assembling the laminated structure body (2a, 6, 9) illustrated in FIG. 19. The negative electrode terminal 2a, the resin member 9, and the conductive member 6 are prepared first, and the top surface of the resin member 9 is bonded (fixed) to the bottom surface of the negative electrode terminal 2a by pressure bonding, as illustrated in FIG. 21. Next, the top surface of the conductive member 6 is positioned to be opposed to the bottom surface of the resin member 9 fixed to the negative electrode terminal 2a so as to be fixed together by pressure bonding. At this point, the projections 92a and 92b of the resin member 9 and the recesses 65a and 65b of the conductive member 6 are led to be engaged (fitted) together, so that the top surface of the conductive member 6 can be strongly fixed to the bottom surface of the resin member 9.

The other configurations of the semiconductor device according to the second embodiment are substantially the same as those of the semiconductor device according to the first embodiment, and overlapping explanations are not repeated below.

The semiconductor device according to the second embodiment has the configuration including the laminated structure body (2a, 6, 9) implemented by the negative electrode terminal 2a, the conductive member 6, and the resin member 9 so as to provide a three-dimensional main wired circuit, and further including the control wired circuit implemented by the printed wiring board (11, 12a to 12e) and the printed wiring board (13, 14a, 14b) for control wiring provided separately from each other. This configuration can decrease the wiring area, so as to achieve a reduction in chip size and cost and further ensure the low inductance properties.

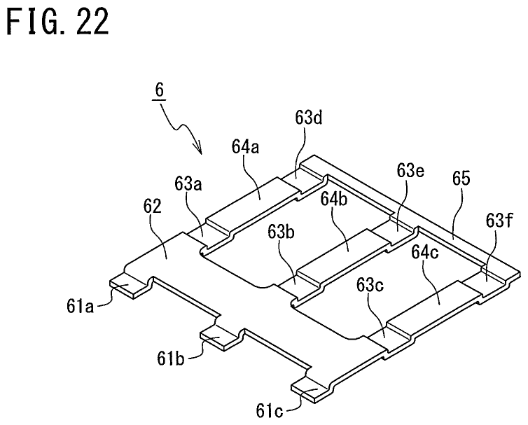

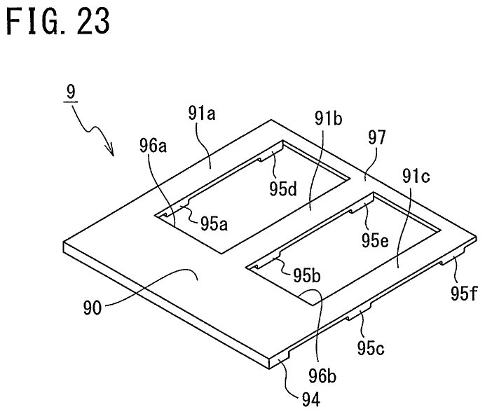

FIG. 22 is a perspective view illustrating another example of the conductive member 6 implementing a part of the laminated structure body (2a, 6, 9). The conductive member 6 illustrated in FIG. 22 differs from the conductive member 6 illustrated in FIG. 11 in further including a connection part 65 connected to the respective chip bonding parts 63d to 63f. FIG. 23 is a perspective view illustrating another example of the resin member 9 implementing a part of the laminated structure body (2a, 6, 9). The resin member 9 illustrated in FIG. 23 differs from the resin member 9 illustrated in FIG. 18 in further including a connection part 97 connected to the respective stripe parts 91a to 91c. The semiconductor device according to the second embodiment may include the laminated structure body (2a, 6, 9) implemented by the conductive member 6 illustrated in FIG. 22 and the resin member 9 illustrated in FIG. 23 in addition to the negative electrode terminal 2a illustrated in FIG. 12.

### Other Embodiments

While the present disclosure has been described above by reference to the first and second embodiments, it should be understood that the present disclosure is not intended to be limited to the descriptions and the drawings composing part of this disclosure. Various alternative embodiments, examples, and technical applications will be apparent to those skilled in the art according to this disclosure.

For example, while the first and second embodiments have been illustrated above with the case of including the conductive substrate 1a and the conductive substrate 1b, the conductive substrate 1a and the conductive substrate 1b may be implemented by a circuit pattern on the top surface side of the insulated circuit substrate such as a direct copper bonded (DCB) substrate. Such an insulated circuit substrate when used may include an insulating substrate such as a ceramic plate, the conductive substrate 1a and the conductive substrate 1b provided on the top surface side of the insulating substrate, and a heat-releasing plate provided on the bottom surface side of the insulating substrate.

Further, the configurations disclosed in the embodiments may be combined as appropriate within a range that does not contradict with the scope of the first and second embodiments. As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

What is claimed is:

1. A semiconductor device comprising:
a conductive substrate;
a plurality of semiconductor chips each having a first electrode and provided on the conductive substrate;
a printed wiring board including a first conductive layer provided on the conductive substrate, an insulating layer provided on the first conductive layer, and a second conductive layer provided on the insulating layer and electrically connected to the respective first electrodes of the semiconductor chips; and
a first external terminal provided on the second conductive layer to extend upward from the second conductive layer.

2. The semiconductor device of claim 1, wherein the first external terminal includes:
a support part provided on the second conductive layer; and
an extending part supported by the support part to extend upward over the second conductive layer.

3. The semiconductor device of claim 2, wherein
the support part has an opening, and
an end of the extending part is press-fitted to the opening.

4. The semiconductor device of claim 1, wherein the insulating layer has a planar pattern including:
a first region extending in one direction between the plural semiconductor chips; and
a second region extending in a direction perpendicular to the first region.

5. The semiconductor device of claim 4, wherein the second conductive layer is arranged across the first region and the second region.

6. The semiconductor device of claim 4, wherein
the semiconductor device further includes a plurality of the first external terminals,
the printed wiring board further includes a plurality of the second conductive layers aligned on the second region, and
the first external terminals are provided on the respective second conductive layers to so as be arranged in line.

7. The semiconductor device of claim 1, wherein
the plural semiconductor chips each further have a second electrode;
the semiconductor device further includes:
a sealing resin provided to seal the respective semiconductor chips; and
a second external terminal electrically connected to the respective second electrodes of the semiconductor chips,
a part of the first external terminal projects from a top surface of the sealing resin, and
a part of the second external terminal projects from a side surface of the sealing resin.
